(19) United States
(12) Patent Application Publication
(10) Pub. No.: US 2006/0113548 A1
(43) Pub. Date: Jun. 1, 2006

(54) LIGHT EMITTING DIODE

(76) Inventors: Ching-Chung Chen, Kaohsiung City (TW); Shin-Min Wu, Yilan County (TW); Ching-An Yang, Kaohsiung County (TW); Wei-Chih Lin, Taichung City (TW); Mei Liu, Pingtung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,770

(22) Filed: Nov. 29, 2004

(51) Int. Cl. H01L 33/00

(52) U.S. Cl. 257/79

(57) ABSTRACT

A light emitting diode is provided, wherein a first semiconductor layer is disposed on a substrate, and a second semiconductor layer is disposed on the first semiconductor layer. The first and the second semiconductor layers are doped with different type dopants. In addition, a second electrode is disposed on the second semiconductor layer, and a first electrode is disposed on the first semiconductor layer to surround the second electrode. A dielectric layer is disposed on the substrate to isolates the first electrode from the second electrode. A redistributing circuit is disposed on the dielectric layer. The redistributing circuit is electrically connected to the first electrode and the second electrode to provide a first extending electrode and a second extending electrode. The light emitting diode can prevent the crowding effect and provide better reliability and light emitting efficiency.

### BACKGROUND OF THE INVENTION

1. Field of the Invention

The present invention relates in general to a semiconductor device. More particularly, the present invention relates to a light emitting diode.

2. Description of Related Art

The light emitting diode is a kind of semiconductor device. The major material of the light emitting chip comprises semiconductor compounds of III-V elements, such as gallium phosphide (GaP), gallium arsenide (GaAs), and gallium nitride (GaN), etc. The principle of a light emitting diode is to convert the electrical energy into light. In other words, when a current is applied to the semiconductor compound, electrons and holes in the semiconductor compound will annihilate to create energy, and this energy is released in the form of light so as to emit light. Since the light emitting diode is a kind of cold luminescence and not lit by heating or discharging, the lifetime of the light emitting diode can be up to about 100 thousand hours and no idling time is required. In addition, the light emitting diode has advantages of quick response time (about 10⁻⁹ sec), small volume, low pollution (mercury free), high reliability and mass productivity, etc. Therefore, the light emitting diode can be widely applied in various fields, such as lamp source for high response scanner, back light for liquid crystal display illumination for car dashboard, traffic signs, and general illumination devices.

The major material of a conventional light emitting diode is gallium nitride (GaN), which is formed by epitaxy. The light emitting diode comprises a substrate, a semiconductor layer and two external electrodes. The semiconductor layer further comprises an N-type doped confinement layer, a P-type doped confinement layer and an active layer between the two confinement layers. When a forward bias is applied to the external electrodes, electrons and holes in the active layer will annihilate so as to make the active layer emit light.

Recently, with continuous increase of the light emitting efficiency of the light emitting diode, daylight lamps and bulbs are gradually replaced by the light emitting diode, and developments of the light emitting diode trend to high power and large area. However, the arrangement of the electrode design of the conventional large area light emitting diode is not ideal; for example, gaps between two electrodes are not consistent. This will cause a non-uniform current distribution in the light emitting diode while driving it, and the light emitting efficiency of the light emitting diode becomes worse. In addition, due to a crowding effect in the vicinity of the electrode while driving the light emitting diode, the electrode or the semiconductor layer near the electrode will be damaged when the local current is too large. As a result, the light emitting diode cannot function normally.

### SUMMARY OF THE INVENTION

According to the foregoing description, an object of this invention is to provide a light emitting diode having a special design for the electrodes. In this manner, the current distribution can be more uniform and the crowding effect can be reduced. Also, a higher reliability and a better light emitting efficiency can be provided.

Another object of this invention is to provide a light emitting diode capable of providing a better locations of extension electrodes by using a redistributing circuit. In this manner, the light emitting diode can be easily connected to the external.

Another object of this invention is to provide a light emitting diode capable of connecting a plurality of light emitting units in series or parallel by using a redistributing circuit. In this manner, a large area light emitting diode can be provided and the current distribution of the light emitting diode can be rendered more uniform.

According to the objects mentioned above, the present invention provides a light emitting diode. The light emitting diode comprises a substrate, a first semiconductor layer, a second semiconductor layer, a first electrode and a second electrode. The first semiconductor layer is disposed on the substrate, and the second semiconductor layer is disposed on the first semiconductor, wherein a peripheral region of the first semiconductor layer is exposed. The first and the second semiconductor layers are respectively doped with dopants of different types. The second electrode is disposed on the second semiconductor layer. The first electrode is arranged on the peripheral region of the first semiconductor layer that is exposed by the second semiconductor layer so as to surround the second electrode.

In addition, the present invention further provides a light emitting diode. The light emitting diode comprises a substrate, a first semiconductor layer, a plurality of second semiconductor layers, a plurality of second electrodes, a plurality of first electrodes, a dielectric layer and a redistributing circuit. The first semiconductor layer is disposed on the substrate, and the second semiconductor layers are disposed on the first semiconductor, wherein a portion region of the first semiconductor layer is exposed. The first semiconductor layer and the second semiconductor layers are respectively doped with dopants of different types. Each of the second electrodes can be disposed on one of the second semiconductor layers. The first electrodes are arranged on the peripheral region of the first semiconductor layer that is exposed by the second semiconductor layer and surround at least one of the second electrodes. The dielectric layer is disposed on the substrate to cover the first semiconductor layer and the second semiconductor layers. The dielectric layer exposes the first electrodes and the second electrodes, and electrically isolates the first electrodes from the second electrodes. The redistributing circuit is disposed on the dielectric layer, and is coupled to the first electrodes and the second electrodes. The redistributing circuit further comprises a first extension electrode and a second extension electrode.

As described above, the first electrode and the second electrode of the light emitting diode of the present invention are arranged in a manner to render current distribution substantially uniform and thereby reduce the crowding effect. Furthermore, the redistributing circuit allows better arrangement of the extension electrodes so that the light emitting diode can be easily connected to the external. Therefore, a lot of light emitting units can be connected in series or parallel by using the redistributing circuit to provide a large area light emitting diode.

### BRIEF DESCRIPTION OF THE DRAWINGS

While the specification concludes with claims particularly pointing out and distinctly claiming the subject matter which is regarded as the invention, the objects and features of the invention and further objects, features and advantages thereof will be better understood from the following description taken in connection with the accompanying drawings.

FIG. 1A is a schematic top view of a light emitting diode according to the first embodiment of the present invention.

FIG. 1B is a cross-sectional view of the light emitting diode along line A-A′ shown in FIG. 1A.

FIG. 2A is a schematic top view of the light emitting diode shown in FIG. 1A after the redistribution.

FIG. 2B is a cross-sectional view of the light emitting diode along line A-A′ shown in FIG. 2A.

FIG. 3 shows a diagram after a heat dissipation device and the light emitting diode of the present invention are jointed together.

FIG. 4A is a schematic top view of a large area light emitting diode according to the second embodiment of the present invention.

FIG. 4B is a cross-sectional view of the light emitting diode along the line B-B′ shown in FIG. 4A.

FIG. 5A is a schematic top view of the light emitting diode shown in FIG. 4A after the redistribution.

FIG. 5B is a cross-sectional view of the light emitting diode along line B-B′ shown in FIG. 5A.

FIG. 6 shows a schematic circuit connection diagram of the light emitting units in FIG. 5A.

FIG. 7A is a schematic top view of a large area light emitting diode according to the third embodiment of the present invention.

FIG. 7B is a cross-sectional view of the light emitting diode along the line C-C′ in FIG. 7A.

FIG. 8A is a schematic top view of the light emitting diode shown in FIG. 7A after the redistribution.

FIG. 8B is a cross-sectional view of the light emitting diode along the line C-C′ in FIG. 8A.

FIG. 9 shows a schematic circuit connection diagram of the light emitting units shown in FIG. 8A.

FIG. 10A is a schematic top view of a large area light emitting diode according to the fourth embodiment of the present invention.

FIG. 10B is a cross-sectional view of the light emitting diode along the line D-D′ shown in FIG. 10A.

FIG. 11A is a schematic top view of the light emitting diode shown in FIG. 10A after the redistribution.

FIG. 11B is a cross-sectional view of the light emitting diode along line D-D′ shown in FIG. 11A.

FIG. 12 shows a schematic circuit connection diagram of the light emitting units shown in FIG. 11A.

### DESCRIPTION OF THE PREFERRED EMBODIMENT

### First Embodiment

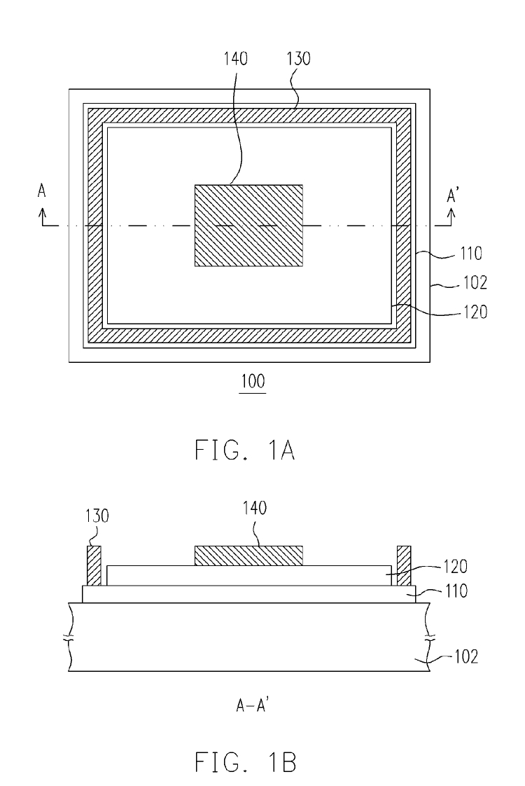

FIG. 1A is a schematic top view of a light emitting diode according to the first embodiment of the present invention, and FIG. 1B is a cross-sectional view of the light emitting diode along line A-A′ shown in FIG. 1A. The light emitting diode 100 comprises, for example but not limited to, a substrate 102, a first semiconductor layer 110 arranged on the substrate 102, and a second semiconductor 120 arranged on the first semiconductor layer 110. The second semiconductor layer 120 is disposed on the first semiconductor layer 110 such that a peripheral region of the first semiconductor layer 110 is exposed. The first semiconductor layer 110 and the second semiconductor layer 120 are respectively doped with dopants of different types. In one embodiment of the present invention, the first semiconductor layer 110 and the second semiconductor layer 120 are respectively doped with N-type dopant and P-type dopant; alternatively, the first semiconductor layer 110 and the second semiconductor layer 120 are respectively doped with P-type dopant and N-type dopant. In this way, a P-N junction is formed between the first semiconductor layer 110 and the second semiconductor layer 120.

Referring to FIGS. 1A and 1B, a second electrode 140 is disposed on the second semiconductor layer 120, and a first electrode 130 is arranged at the peripheral of the first semiconductor layer 110 to encompass the first semiconductor layer 110. The second electrode 140 can be a rectangular shape, and the first electrode 130 can be a rectangular frame in shape for example, corresponding to the second electrode 140. When a forward bias is applied to the first electrode 130 and the second electrode 140, electrons and holes at the P-N junction between the first semiconductor layer 110 and the second semiconductor layer 120 will annihilate to create and emit photons (light rays).

As described above, the first electrode 130 is arranged in a manner to surround the second electrode 140, so that the current distribution between the first electrode 130 and the second electrode 140 can be rendered more uniform to effectively reduce the crowding effect. In one embodiment of the present invention, the first electrode 130 can surround the second electrode 140 along the outer rim of the second electrode 140. In this way, the distance between the first electrode 130 and the second electrode 140 can be substantially equidistant to provide a better driving effect. In addition, the shapes of the second electrode 140 and the first electrode 130 can be respectively rectangle and rectangular frame as shown in FIG. 1A, circle and circular ring, polygon and polygon frame, or other corresponding combinations of shapes can also be used.

According to the present invention, the arrangement of the first electrode and the second electrode can provide a more uniform current distribution to reduce the crowding effect in the vicinity of the electrodes, so that the light emitting diode can have a better light emitting efficiency. However, in the subsequent processes, the light emitted diode is usually jointed with other elements, such as heat dissipation fins or circuit carrier. Therefore, for conducing to following joint processes, a redistribution process can be performed on the electrodes of the light emitting diode of the present invention, such as lithography, wet etching or evaporation, etc. Therefore, extension electrodes serving as better joint positions are formed on the light emitting diode.

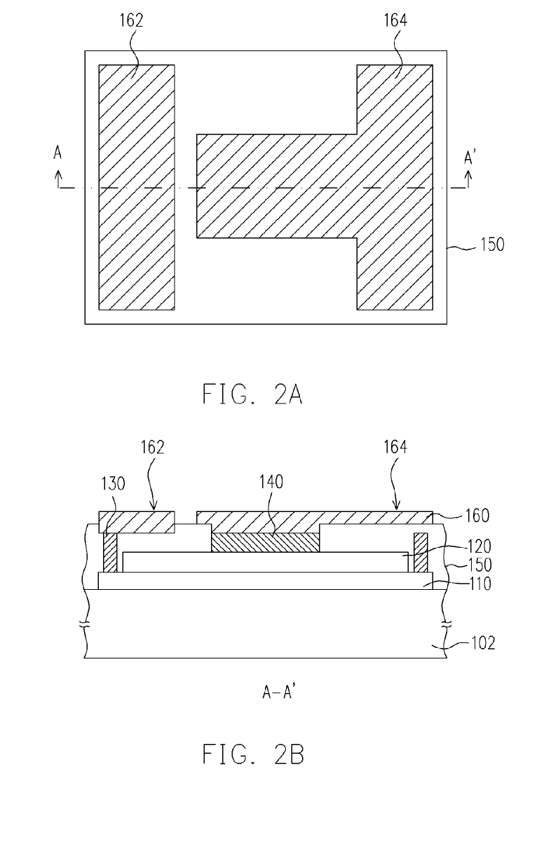

FIG. 2A is a schematic top view of the light emitting diode shown in FIG. 1A after the redistribution, and FIG. 2B is a cross-sectional view of the light emitting diode along line A-A′ shown in FIG. 2A. As shown in FIGS. 2A and 2B, a dielectric layer 150 is disposed on the substrate 102 to cover the first semiconductor 110 and the second semiconductor layer 120. The dielectric layer 150 exposes the first electrode 130 and the second electrode 140, and electrically isolates the first electrode 130 from the second electrode 140. The material of the dielectric layer 150 can be any suitable insulating material such as silicon dioxide, silicon nitride, etc. Alternatively, diamond-like carbon or diamond with a high heat dissipation coefficient can constitute a material of the dielectric layer 150. In addition, a redistributing circuit 160 is arranged on the dielectric layer 150, and comprises a first extension electrode 162 and a second extension electrode 164. The first extension electrode 162 and the second extension electrode 164 are located at opposite sides of the substrate 102. The first extension electrode 162 is coupled to the first electrode 130, which is located underneath the first extension electrode 162 and the second extension electrode 164 is coupled to the second electrode 140, which is located underneath the first extension electrode 164.

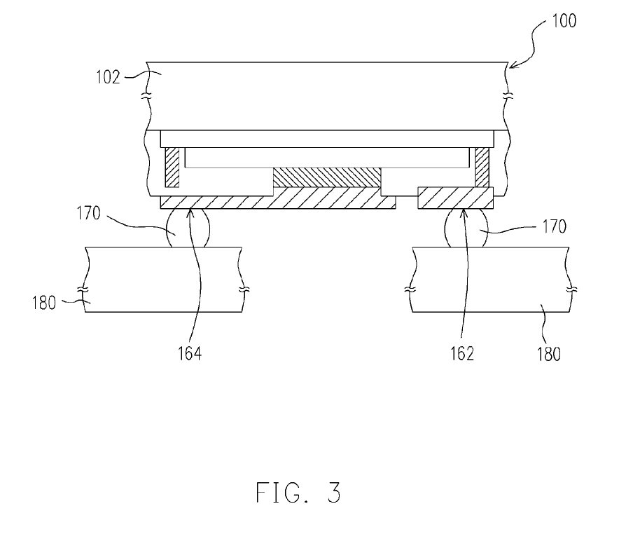

After redistributing the light emitting diode of the present invention, the extension electrodes are respectively provided at the opposite sides of the light emitting diode, conducing to the subsequent joint processes. FIG. 3 shows a diagram after a heat dissipation device and the light emitting diode of the present invention are jointed. As shown in FIG. 3, the light emitting diode 100 is jointed to a metal heat dissipation plate 180 by flip chip, and can be coupled to the external through the metal heat dissipation plate 180. The first extension electrode 162 and the second extension electrode 164 are respectively coupled to the metal heat dissipation plate 180 through bumps 170. The material of the metal heat dissipation plate 180 can be metal such as copper or silver, etc. that is easy to conduct heat. Since the first extension electrode 162 and the second extension electrode 164 are located at the opposite side of the light emitting diode 100, the metal heat dissipation plate 180 can be easily jointed to the light emitting diode 100. Furthermore, in other embodiments of the present invention, the light emitting diode 100 can also be directly jointed to a driving circuit board (not shown) or other circuit carrier (not shown). By using the redistributing circuit 160, the first extension electrode 162 and the second extension electrode 164 can be adjusted to the desired locations corresponding to a circuit board. Therefore, the layout of the circuit board (not shown) can be more flexible because of the adjustment of the first extension electrode 162 and the second extension electrode 164.

Based on the light emitting diode of the first embodiment, the present invention can provide a plurality of light emitting units on the same substrate for obtaining a light emitting diode with a large area (a large emitting area). The light emitting unit can comprise elements of a first semiconductor layer, a second semiconductor layer, a first electrode and a second electrode, etc. on the substrate. In addition, by arranging the first and the second electrodes between different light emitting units and the layout design of the redistributing circuit, the connection among the light emitting units can be serial or parallel so as to provide various driving effects. The second to the fourth embodiments will describe different types of large area light emitting diodes in detail as follows.

### Second Embodiment

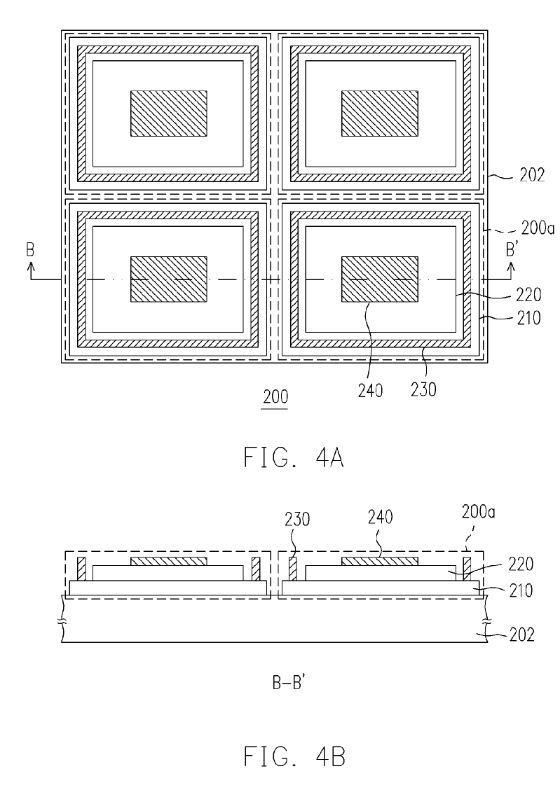

FIG. 4A is a schematic top view of a large area light emitting diode according to the second embodiment of the present invention, and FIG. 4B is a cross-sectional view of the large area light emitting diode along the line B-B′ shown in FIG. 4A. For example, a plurality of first semiconductor layers 210 is formed on a substrate 202 of a light emitting diode 200, and a second semiconductor layer 220 is disposed on each of the first semiconductor layers 210. In addition, a first electrode 230 and a second electrode 240 are respectively arranged on the first semiconductor layer 210 and the second semiconductor layer 220. Each first electrode 230 is disposed in a manner to surround the corresponding second electrode 240. In this manner, an array formed by a plurality of light emitting units 200a is constructed.

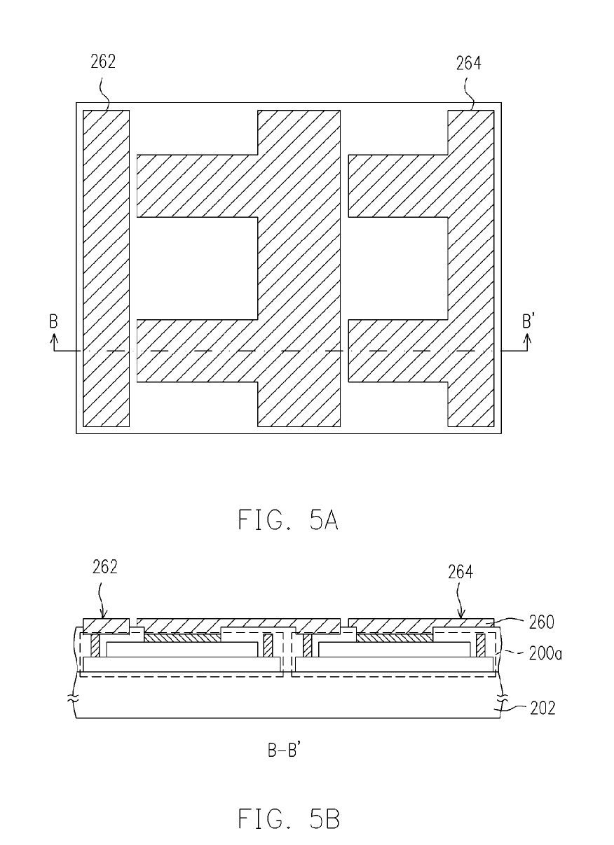

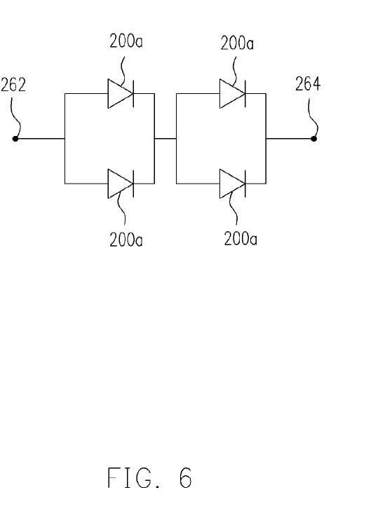

FIG. 5A is a schematic top view of the light emitting diode in FIG. 4A after the redistribution, and FIG. 5B is a cross-sectional view along line B-B′ in FIG. 5A. FIG. 6 shows a schematic circuit connection diagram of the light emitting units 200a. By using the redistributing circuit 260, the light emitting units 200a at the same column can be connected in series, and the light emitting units 200a of the same column are connected in parallel. The redistributing circuit 260 further comprises a first extension electrode 262 and a second extension electrode 264 that are respectively arranged at two sides of the substrate 202.

### Third Embodiment

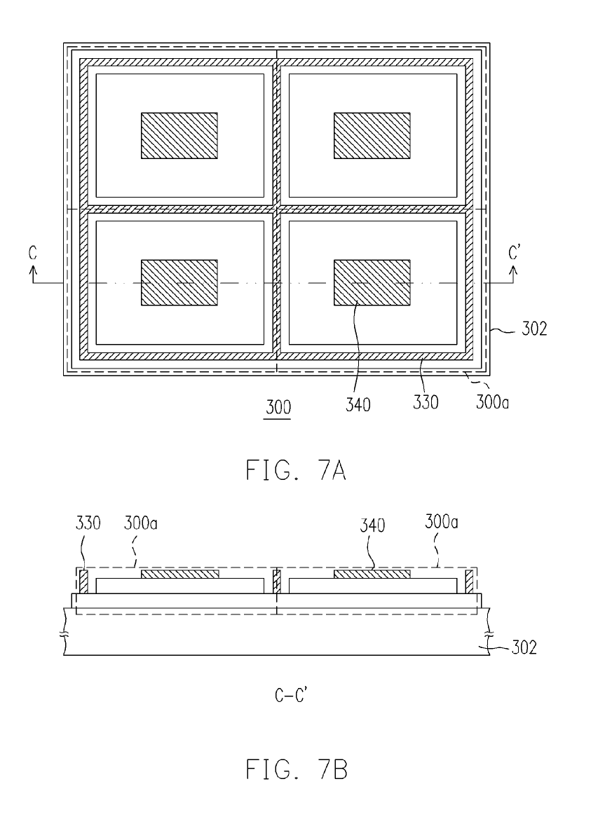

FIG. 7A is a schematic top view of a large area light emitting diode according to the third embodiment of the present invention, and FIG. 7B is a cross-sectional view of the large area light emitting diode along the line C-C′ shown in FIG. 7A. A plurality of light emitting units 300a is formed on a substrate 302 of a light emitting diode 300. The first electrode 330 of each light emitting unit 300a is arranged adjacent to each other, and each first electrode 330 surrounds its corresponding second electrode 340.

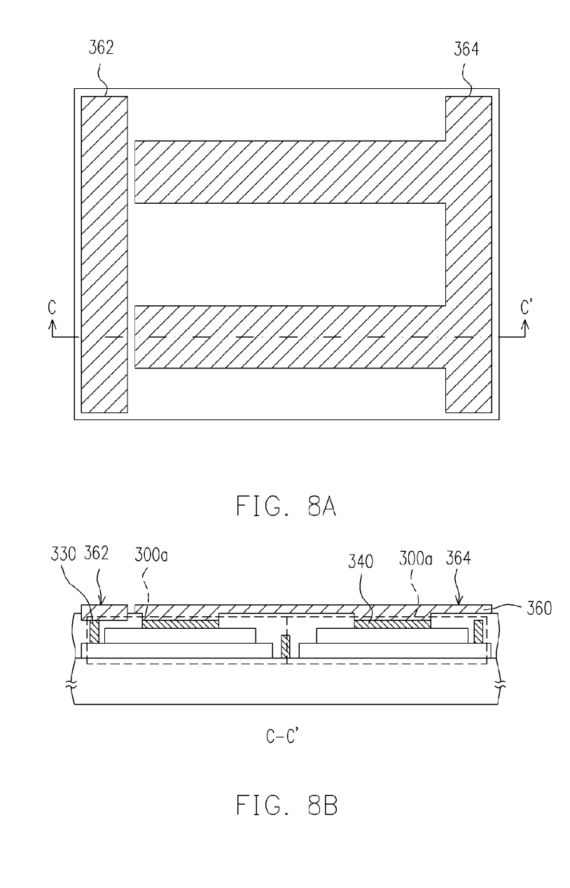

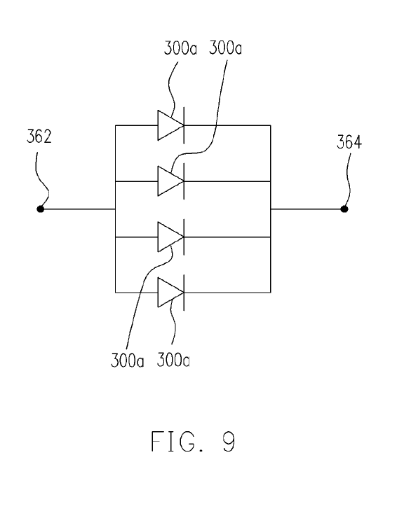

In addition, FIG. 8A is a schematic top view of the light emitting diode shown in FIG. 7A after the redistribution, and FIG. 8B is a cross-sectional view of the light emitting diode along line C-C′ shown in FIG. 8A. FIG. 9 shows a schematic circuit connection diagram of the light emitting units 300a. The first electrode 330 of each light emitting unit 300a is coupled to each other, and then coupled to the first extension electrode 362 through the redistributing circuit 360. In addition, the second electrode 340 of each light emitting unit 300a is coupled to the second extension electrode 364 through the redistributing circuit 360 so that the light emitting units 300a are connected in parallel.

### Fourth Embodiment

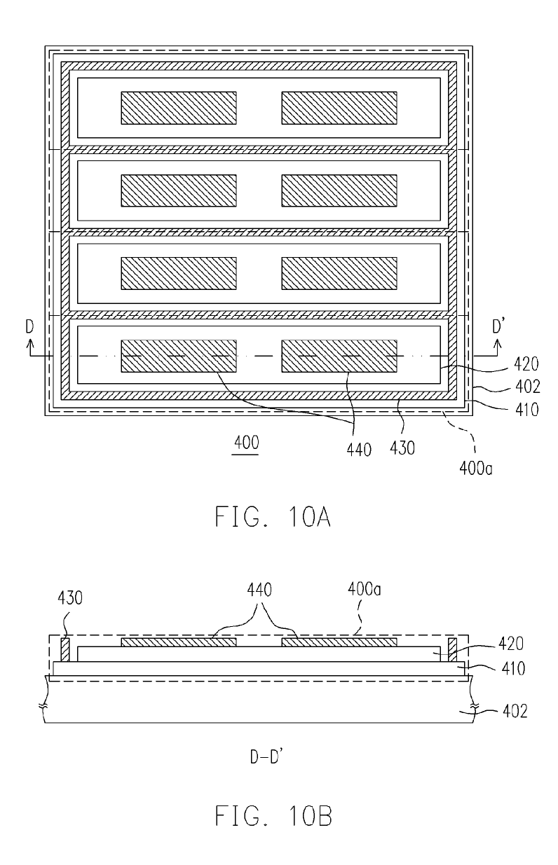

FIG. 10A is a schematic top view of a large area light emitting diode according to the fourth embodiment of the present invention, and FIG. 10B is a cross-sectional view of the large area light emitting diode along the line D-D′ shown in FIG. 10A. For example, a first semiconductor layer 410 is formed on a substrate 402 of a light emitting diode 402, and a plurality of second semiconductor layer 420 is disposed on the first semiconductor layer 410. A plurality of second electrodes 440 is disposed on the second semiconductor layer, and a first electrode 430 on the first semiconductor layer 410 is arranged to surround the second electrodes 440 on the second semiconductor layer 440. In this way, a plurality light emitting units 400a is constructed.

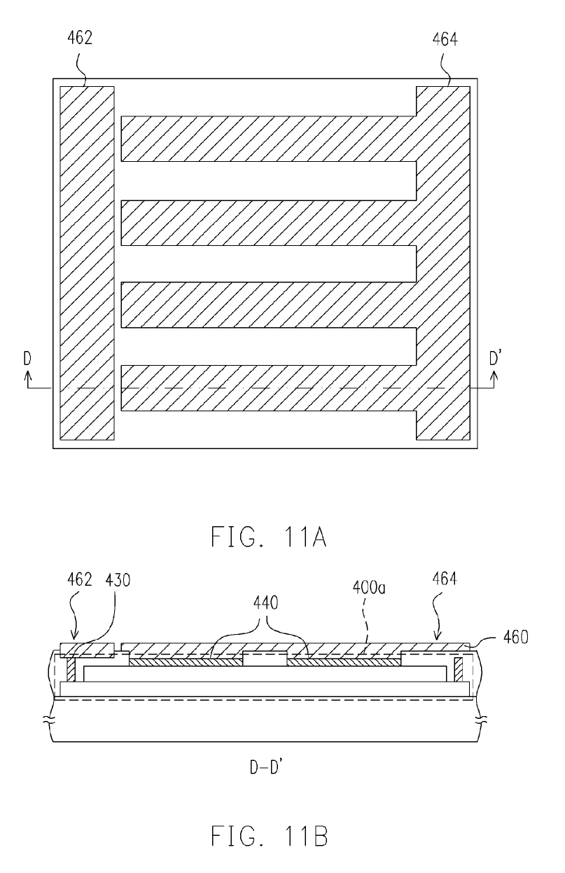

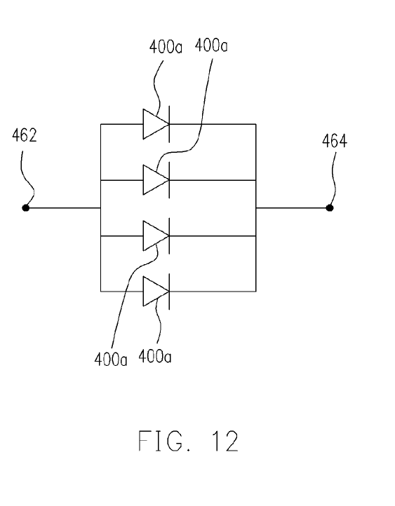

FIG. 11A is a schematic top view of the light emitting diode in FIG. 10A after the redistribution, and FIG. 11B is a cross-sectional view of the light emitting diode along line D-D′ shown in FIG. 11A. FIG. 12 shows a schematic circuit connection diagram of the light emitting units 400a. The first electrode 430 of each light emitting unit 400a is adjacent to each other, and then coupled to the first extension electrode 462 through the redistributing circuit 460, and the second electrodes 440 are coupled to the second extension electrode 464 through the redistributing circuit 460 so that the light emitting units 400a are connected in parallel.

As described above, the light emitting diode of the present invention has at least the following advantages. The first electrode and the second electrode are arranged by a special design. Therefore, a more uniform current distribution can be provided to effectively reduce the crowding effect. Furthermore, the light emitting diode of the present invention can have a higher reliability and a better light emitting efficiency.

Furthermore, the redistributing circuit provides the extension electrodes at better locations. In this way, the light emitting diode can be easily connected to the external.

Moreover, a plurality of light emitting units is connected in series or parallel by using the redistributing circuit so as to provide various driving modes. In this way, a large area light emitting diode can be provided and the current distribution can be rendered more uniform.

While the present invention has been described with a preferred embodiment, this description is not intended to limit our invention. Various modifications of the embodiment will be apparent to those skilled in the art. It is therefore contemplated that the appended claims will cover any such modifications or embodiments as fall within the true scope of the invention.

What is claimed is:

1. A light emitting diode, comprising:
a substrate;
a first semiconductor layer disposed on the substrate;
a second semiconductor layer disposed on the first semiconductor to expose a peripheral region of the first semiconductor layer, wherein the first and the second semiconductor layers are respectively doped with dopants of different types;
a second electrode disposed on the second semiconductor layer; and
a first electrode arranged on the peripheral region of the first semiconductor layer that is exposed by the second semiconductor layer, and surrounding the second electrode.

2. The light emitting diode of claim 1, further comprising a dielectric layer disposed on the substrate to cover the first and the second semiconductor layers, wherein the dielectric layer exposes the first and the second electrodes, and electrically isolates the first electrode from the second electrode.

3. The light emitting diode of claim 2, further comprising a redistributing circuit disposed on the dielectric layer, wherein the redistributing circuit comprises a first extension electrode and a second extension electrode, and wherein the first extension electrode is coupled to the first electrode and the second extension electrode is coupled to the second electrode.

4. The light emitting diode of claim 3, wherein the first extension electrode and the second extension electrode are respectively located at opposite sides of the substrate.

5. The light emitting diode of claim 1, wherein the first electrode surrounds the second electrode along an outer rim of the second electrode.

6. The light emitting diode of claim 5, wherein a shape of the second electrode is rectangle or circle.

7. The light emitting diode of claim 1, wherein the first semiconductor layer is doped with a P-type dopant, and the second semiconductor layer is doped with a N-type dopant.

8. The light emitting diode of claim 1, wherein the first semiconductor layer is doped with a N-type dopant, and the second semiconductor layer is doped with a P-type dopant.

9. A light emitting diode, comprising:
a substrate;
a first semiconductor layer disposed on the substrate;
a plurality of second semiconductor layers disposed on the first semiconductor to expose a portion region of the first semiconductor layer, wherein the first semiconductor layer and the second semiconductor layers are respectively doped with dopants of different types;
a plurality of second electrodes each disposed on one of the second semiconductor layers;
a plurality of first electrodes arranged on the peripheral region of the first semiconductor layer that is exposed by the second semiconductor layer, and surrounding at least one of the second electrodes;
a dielectric layer disposed on the substrate to cover the first semiconductor layer and the second semiconductor layers, wherein the dielectric layer exposes the first electrodes and the second electrodes, and electrically isolates the first electrodes from the second electrode; and
a redistributing circuit disposed on the dielectric layer, wherein the redistributing circuit is coupled to the first electrodes and the second electrodes, and the redistributing circuit comprises a first extension electrode and a second extension electrode.

10. The light emitting diode of claim 9, wherein the first extension electrode and the second extension electrode are respectively located at opposite sides of the substrate.

11. The light emitting diode of claim 9, wherein the first electrodes surrounds the second electrodes along outer rims of the corresponding second electrodes.

12. The light emitting diode of claim 11, wherein a shape of the second electrodes is rectangle or circle.

13. The light emitting diode of claim 9, wherein the first electrodes are adjacent to each other.

14. The light emitting diode of claim 9, wherein the first semiconductor layer is doped with a P-type dopant, and the second semiconductor layer is doped with a N-type dopant.

15. The light emitting diode of claim 9, wherein the first semiconductor layer is doped with a N-type dopant, and the second semiconductor layer is doped with a P-type dopant.

16. The light emitting diode of claim 9, wherein each of the second semiconductor layers has a second electrode disposed thereon.

17. The light emitting diode of claim 9, wherein each of the second semiconductor layers has a plurality of second electrodes disposed thereon.
